(19) United States
(12) Patent Application Publication
(10) Pub. No.: US 2017/0215307 A1
(43) Pub. Date: Jul. 27, 2017

(54) Shielded Cable Terminal Assembly

(71) Applicant: Delphi Technologies, Inc., Troy, MI (US)

(72) Inventors: Terry A. Morgan, Warren, OH (US); William C. Ketterer, Girard, OH (US); Bruce D. Taylor, Cortland, OH (US); Eric B. Poma, Hubbard, OH (US)

(21) Appl. No.: 15/007,272

(22) Filed: Jan. 27, 2016

(51) Int. Cl. H05K 9/00; H01R 9/05

(52) U.S. Cl. CPC H05K 9/0075; H01R 9/0518

(57) ABSTRACT

A terminal assembly configured to terminate the shield of a shielded cable having an inner conductor, an inner insulator surrounding the inner conductor, an outer conductor forming a shield surrounding the inner insulator, and an outer insulator surrounding the outer conductor. The terminal assembly includes a generally cylindrical outer ferrule formed of a conductive material and a generally cylindrical inner ferrule formed of a resilient compressible dielectric material. At least a portion of the inner ferrule is disposed within the outer ferrule and a portion of the shielded cable is disposed within the inner ferrule. A portion of the outer conductor is disposed intermediate the inner and outer ferrules and is in intimate contact therewith.

### TECHNICAL FIELD OF THE INVENTION

The invention relates to a terminal assembly for an electrically shielded wire cable, particularly a terminal assembly having a resiliently compressible inner ferrule.

### BACKGROUND OF THE INVENTION

Braided shields of shielded cables are currently terminated by placing the braids of the shield between a metal inner and outer ferrule before crimping. An example of a terminal assembly suing these ferrules is shown in FIGS. 1A-1D. The outer insulation of the cable 112 is first removed to expose the braided shield 118 and the braids of the shield are then flared and a metallic tubular inner ferrule 122 is placed between the braids 118 and the inner insulation 114 of the shielded cable 112 (see FIG. 1A). A metallic tubular outer ferrule 132 is placed over the braided shield 118 and inner ferrule 122 (see FIG. 1B) and then crimped 136 to secure the outer ferrule 132 to shielded cable 112 (see FIGS. 1C and 1D).

The difference between the inner diameter of the outer ferrule 132 and the outer diameter of the inner ferrule 122 is typically about 1 millimeter. Thick inner ferrules can degrade the strength of the crimp possibly reducing pull off force and increasing shield to outer ferrule electrical resistance. Thin inner ferrules can rupture during crimping. Rupture of the inner ferrule 122 could cause undesirable electrical contact and shorting of the inner conductor 114 and the braided shield 118. Therefore, the inner and outer ferrule diameters must be carefully matched and different cable sizes and applications require different sized inner and outer ferrules. The inner and outer ferrules are formed by either deep draw stamping or machining; both of these manufacturing methods are relatively expensive. These inner and outer ferrule sizes may differ only slightly for different shielded cables which may make it difficult to visually distinguish between different sized inner or outer ferrules. Applying markings, such as color coding, may be used to help identify different ferrules. However, applying these markings is an additional manufacturing process that undesirably increases ferrule manufacturing time and cost. Therefore, a reliable ferrule assembly that can easily accommodate different cable sizes remains desired.

The subject matter discussed in the background section should not be assumed to be prior art merely as a result of its mention in the background section. Similarly, a problem mentioned in the background section or associated with the subject matter of the background section should not be assumed to have been previously recognized in the prior art. The subject matter in the background section merely represents different approaches, which in and of themselves may also be inventions.

### BRIEF SUMMARY OF THE INVENTION

In accordance with an embodiment of the invention, a terminal assembly is provided. The terminal assembly is configured to terminate a shielded cable having an inner conductor, an inner insulator surrounding the inner conductor, an outer conductor surrounding the inner insulator, and an outer insulator surrounding the outer conductor. terminal assembly includes a generally cylindrical outer ferrule formed of a conductive material and a generally cylindrical inner ferrule formed of a resilient compressible dielectric material. At least a portion of the inner ferrule is disposed within the outer ferrule and a portion of the shielded cable is disposed within the inner ferrule. A portion of the outer conductor is disposed intermediate the inner and outer ferrules and is in intimate contact therewith. As used herein, generally cylindrical means that the inner and outer ferrules are cylindrical within the typical manufacturing tolerances and variations of the methods used to form the ferrules.

The resilient compressible dielectric material may be a silicone-based material. The resilient compressible dielectric material may have a Shore A durometer hardness between 30 and 80. The inner ferrule may have a generally constant outside diameter. The outer ferrule may be crimped to the inner ferrule and the inner ferrule may be deformed by the outer ferrule. An inner surface of the outer ferrule may define a projection configured to contact and indent the outer conductor and the inner ferrule. The inner ferrule may define a circumferential rib protruding beyond the outer ferrule. The inner ferrule may define a plurality of circumferential ribs protruding beyond the outer ferrule and the outer diameter of each circumferential rib may be substantially uniform. The plurality of circumferential ribs may be resilient. As used herein, substantially uniform means that the outer diameter of each circumferential rib is ±5% the same diameter of every other circumferential rib in the plurality of circumferential ribs.

In accordance with another embodiment, a terminal assembly terminating a shielded cable wherein a metallic inner wire cable covered by an inner insulator is sheathed by braided metallic wires on an outer periphery of the inner insulator and further covered by an outer insulator surrounding the braided metallic wires and wherein the braided metallic wires are exposed at one end of the shielded cable is provided. The terminal assembly includes a generally cylindrical inner ferrule formed of a resilient compressible dielectric material inserted between the outer insulator and the exposed braided metallic wires bent back over the inner ferrule and a generally cylindrical outer ferrule formed of a conductive material crimped over the exposed braided metallic wires. At least a portion of the inner ferrule is disposed within the outer ferrule and wherein a portion of the exposed braided metallic wires are disposed intermediate the inner and outer ferrules and is in intimate contact therewith.

The resilient compressible dielectric material may be a silicone-based material. The resilient compressible dielectric material may have a Shore A durometer hardness between 30 and 80. The inner ferrule may have a generally constant outside diameter. An inner surface of the outer ferrule may define a projection configured to contact and indent the outer conductor and the inner ferrule. The inner ferrule may define a circumferential rib protruding beyond the outer ferrule. The inner ferrule may define a plurality of circumferential ribs protruding beyond the outer ferrule and the outer diameter of each circumferential rib may be substantially uniform. The plurality of circumferential ribs may be resilient.

### BRIEF DESCRIPTION OF THE SEVERAL VIEWS OF THE DRAWING

The present invention will now be described, by way of example with reference to the accompanying drawings, in which:

FIGS. 1A-1D are perspective side views illustrating a method of forming a terminal assembly having a metallic inner and outer ferrule according to the prior art;

FIGS. 2-6 are perspective side views illustrating a method of forming a terminal assembly having a metallic outer ferrule and a resilient inner ferrule according to one embodiment;

FIG. 7 is a perspective side view of an inner ferrule of the terminal assembly of FIGS. 2-6 according to one embodiment;

FIG. 8 is a cross section view of terminal assembly of FIGS. 1A-1D according to the prior art;

FIG. 9 is a cross section view of terminal assembly of FIGS. 2-6 according to one embodiment;

FIG. 10 is a side perspective view of a terminal assembly incorporating anti-creepage features in the inner ferrule according to one embodiment;

FIG. 11 is a side perspective view of a terminal assembly incorporating anti-vibration features in the inner ferrule according to one embodiment; and

FIG. 12 is a side perspective view of a terminal assembly incorporating cable seal features in the inner ferrule according to one embodiment.

### DETAILED DESCRIPTION OF THE INVENTION

Presented herein is a terminal assembly including features configured to terminate a shield of a shielded cable having an inner conductor, an inner insulator surrounding the inner conductor, an outer conductor surrounding the inner insulator, and an outer insulator surrounding the outer conductor. The terminal assembly includes a generally cylindrical outer ferrule that is formed of a conductive material and a generally cylindrical inner ferrule that s formed of a resilient compressible dielectric material. The inner ferrule is placed over an end portion of the shielded cable. A portion of the outer insulator is removed and an exposed portion of the outer conductor is placed over the inner ferrule and the outer ferrule is then placed over the inner ferrule. The outer ferrule is then crimped to retain the terminal assembly to the shielded cable, plastically deforming the outer ferrule and elastically deforming the inner ferrule. The exposed portion of the outer conductor is disposed intermediate the inner and outer ferrules and is in intimate contact therewith.

Reference numbers for similar features in the drawings and the description of the prior art and the various embodiments of the invention share the last two digits.

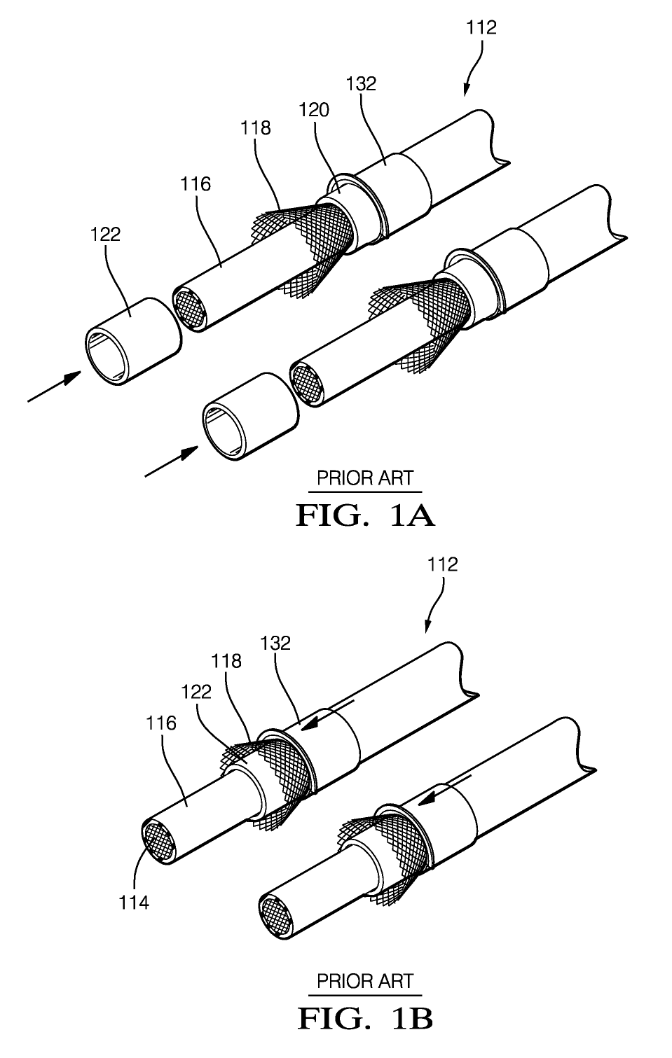

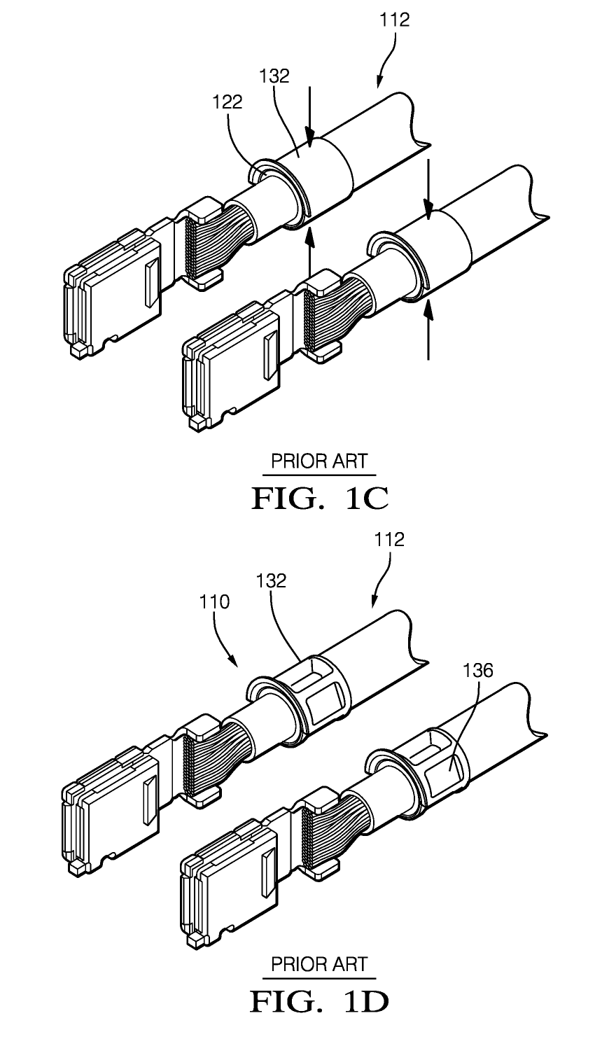

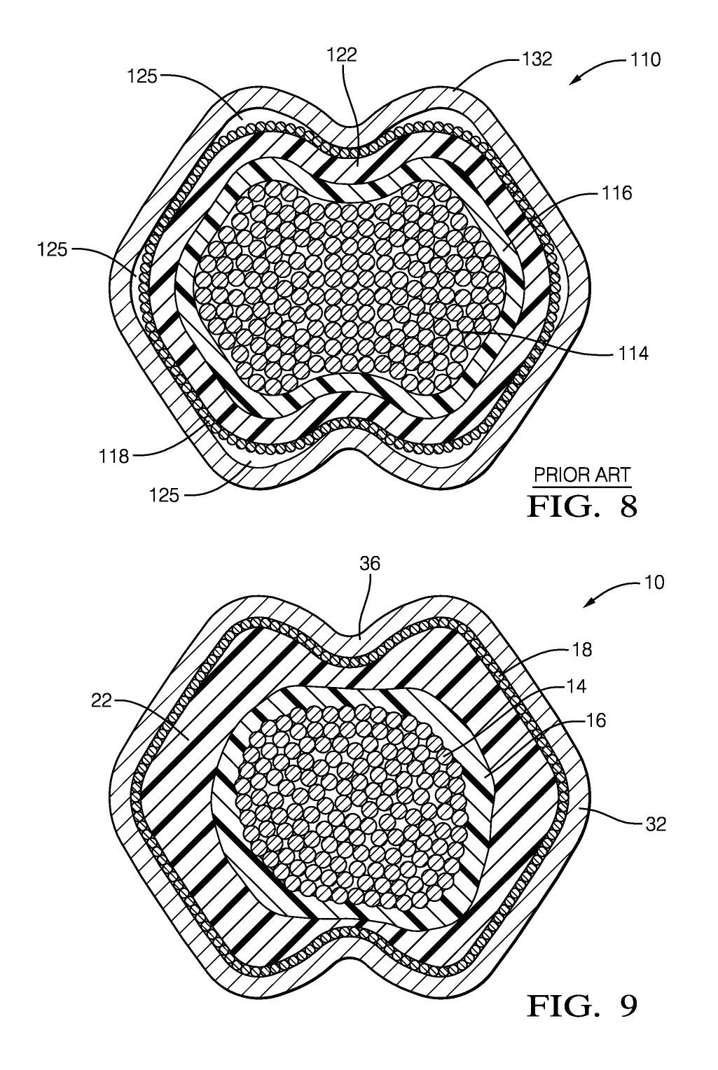

By referring now to the drawings, embodiments of the invention will be explained below. It will be appreciated that the terminal assemblies shown in FIGS. 1A-1D and FIG. 8 do not fall within the scope of the claims but are provided here as they clarify the scope of the invention.

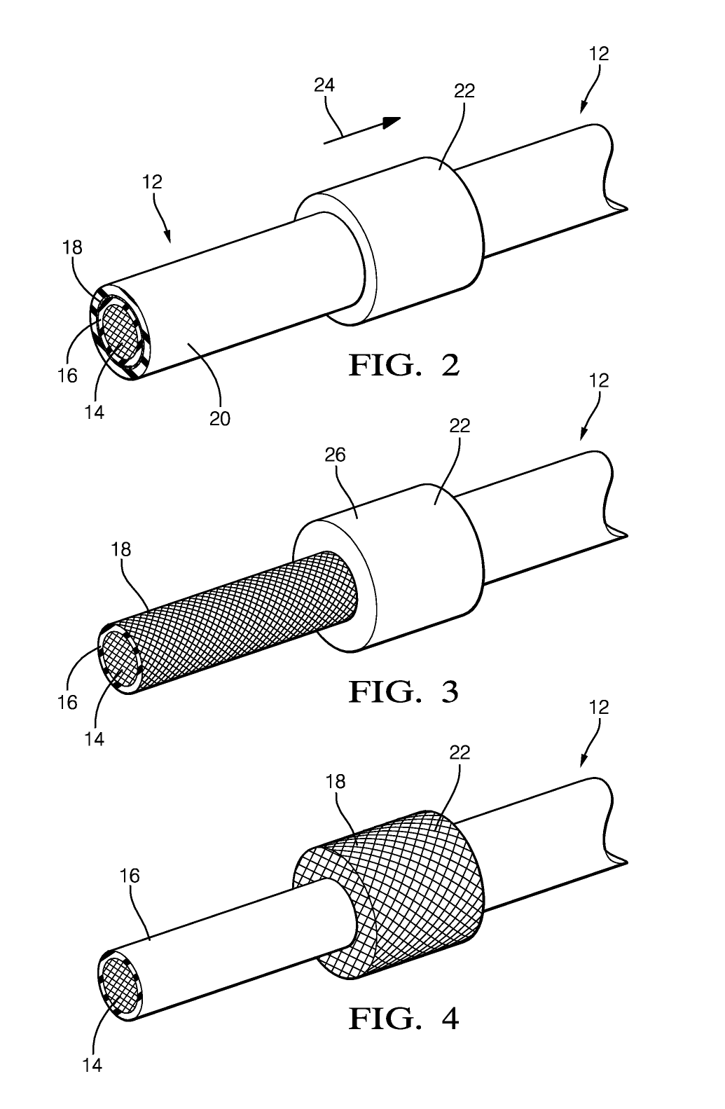

FIGS. 2-7 show a non-limiting example of a terminal assembly 10 configured to terminate a shield of a shielded cable 12 and a method of forming such a terminal assembly 10. As shown in FIG. 2, the shielded cable 12 includes an inner conductor 14 comprising metallic core wires, a first or inner insulator 16 surrounding the inner conductor 14, an outer conductor 18 formed of braided metallic wires which sheathe the inner insulator 16, and a second or outer insulator 20 that covers the outer conductor 18. A sleeve-like body or generally cylindrical inner ferrule 22 having an inner diameter sufficient to receive the shielded cable 12 is slid over an end portion of the shielded cable 12 in a direction shown by arrow 24.

As shown in FIG. 7, the outer surface 26 of the inner ferule 22 has a generally uniform outer diameter. Leading and trailing edges 28, 30 of the inner ferrule 22 may be beveled. The inner ferrule 22 is formed of a resilient compressible dielectric material. The resilient compressible dielectric material is an elastomeric material having a Shore A durometer hardness between 30 and 80, such as silicone-based material. The inner ferrule 22 merely serves to support the outer conductor 18 and does not need to electrically communicate with the outer conductor 18. The inner ferrule 22 may be formed by an injection molding process.

Although the inner ferrule 22 is formed into a complete cylindrical body in the embodiment shown in FIGS. 2-7, the inner ferrule may alternatively comprise a pair of half parts divided axially or may be provided with a slit extending axially since the inner ferrule could be brought into a complete cylinder when it is assembled on the shielded cable and may simplify the step of mounting the inner ferrule to the shielded cable.

Looking now at FIG. 3, the shielded cable 12 is stripped at one end so that at least a portion of the outer insulator 20 is removed exposing the braided wires of the outer conductor 18. Then, as shown in FIG. 4, the braided wires of the outer conductor 18 are flared and pulled back over the inner ferrule 22 covering at least a portion of the outer surface 26 of the inner ferrule 22.

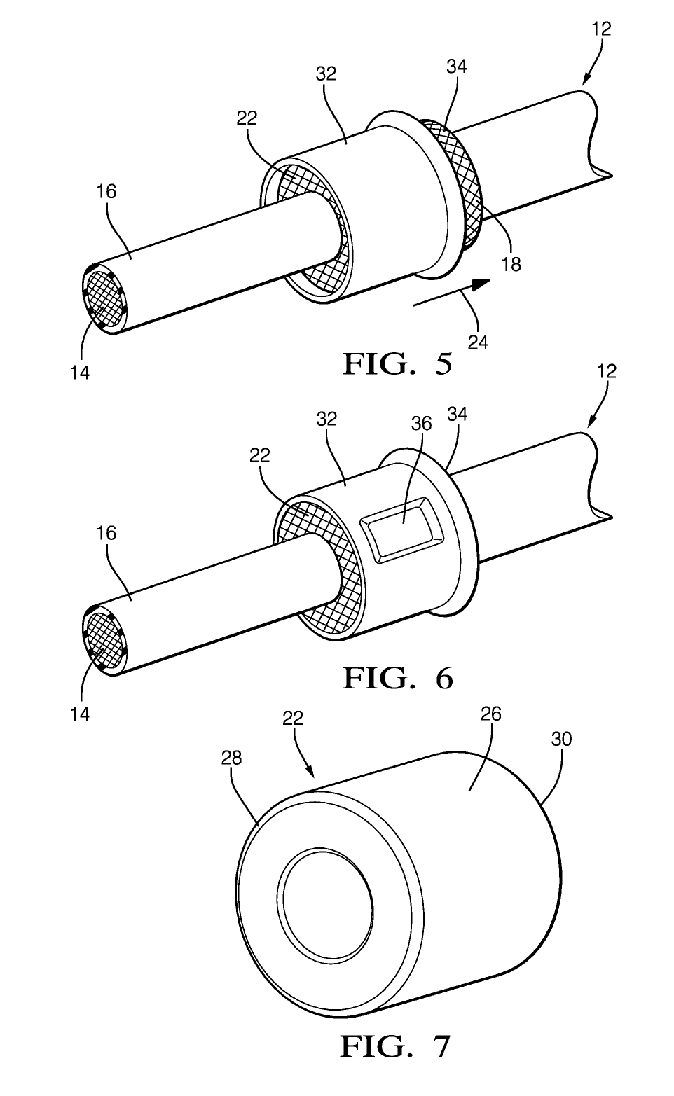

Next, as shown in FIG. 5, another sleeve-like body or generally cylindrical outer ferrule 32 having an inner diameter sufficient to receive the inner ferrule 22 and braided wires of the outer conductor 18 coving the inner ferrule 22 is slid over at least a portion of the inner ferrule 22 in the direction shown by arrow 24. The outer ferrule 32 is formed of a conductive metallic material, such as a tin plated copper alloy. The outer ferrule 32 may be formed by a deep draw stamping process or a machining process. At least one open end 34 of the outer ferrule 32 has an opening as large as the inner diameter of the outer ferrule 32.

Finally, as shown in FIG. 6, the outer ferrule 32 is crimped, i.e. indentations 36 are formed in the outer ferrule 32, thereby plastically deforming the outer ferrule 32 and elastically deforming the inner ferrule 22 in order to retain the terminal assembly 10 to the shielded cable 12 and putting the outer ferrule 32 and inner ferrule 22 in intimate contact with the outer conductor 18 therebetween. The outer ferrule 32 may then be electrically connected to an electrical ground (not shown) such as a conductive casing.

FIG. 8 illustrates an example of a cross section of a crimped terminal assembly 110 having a metallic outer ferrule 132 and a metallic inner ferrule 122 according to the prior art. The outer ferrule 132 and the inner ferrule 122 are both plastically deformed during the crimping process. As can be seen, there are voids 125 between inner ferrule 122 and the outer ferrule 132 that may reduce the pull off force needed to pull the terminal assembly 110 off of the shielded cable and could allow water and other contaminants to enter the terminal assembly 110 causing corrosion that could increase electrical resistance between the outer conductor 118 and the outer ferrule 132 and further reduce pull off force. In addition, there are a number of the strands of the braided wires of the outer conductor 118 that are not in contact with the outer ferrule 132 which may further increase electrical resistance between the outer conductor 118 and the outer ferrule 132.

FIG. 9 illustrates a cross section of the terminal assembly 10 shown in FIGS. 2-7 and described above. In contrast to the terminal assembly 10 shown in FIG. 8, the number and size of voids is greatly reduced. Further, there are fewer strands of the strands of the braided wires of the outer conductor 18 that are not in contact with the outer ferrule 32.

Through testing, the terminal assembly 110 of FIG. 8 has been found to have a pull off force of about 560 newtons while the terminal assembly 10 of FIG. 9 has been found to have a pull off force of about 690 newtons, meeting or exceeding the pull off force performance of terminal assembly 110. Without subscribing to any particular theory of operation, the elastic deformation of the inner ferrule 22 provides the reduction of voids between the inner and outer ferrule 32 and may contribute to improved pull off force performance compared with the prior art terminal assembly 110. In addition, testing by the inventors has found that the resistance between the outer conductor 18 and the outer ferrule 32 of the terminal assembly 10 is comparable to the terminal assembly 110.

It may be appreciated that the terminal assembly 10 has a reduced likelihood of short circuit between the outer ferrule 32 or outer conductor 18 and the inner conductor 14 since the inner ferrule 22 is also an insulating body rather than a conductive body as seen in prior art terminal assemblies, e.g. FIG. 8.

In addition, it may be recognized that an outer ferrule 32 having one specific inner diameter may be used with multiple shielded cable 12 diameters by merely varying the inner and outer diameter of the resilient inner ferrule 22, since it is no longer necessary to maintain a difference between the inner diameter of the outer ferrule 32 and the outer diameter of a metallic inner ferrule 22 of about 1 millimeter to avoid issues of thick inner ferrules can degrade the strength of the crimp and thin inner ferrules can rupture during crimping described in the BACKGROUND OF THE INVENTION section above. This will reduce the number of different outer ferrule designs and part numbers required to accommodate different cable sizes. The inner ferrule 22 can easily be color coded to identify different inner ferrule 22 sizes by adding a colorant to the elastomeric material prior to molding the inner ferrule 22.

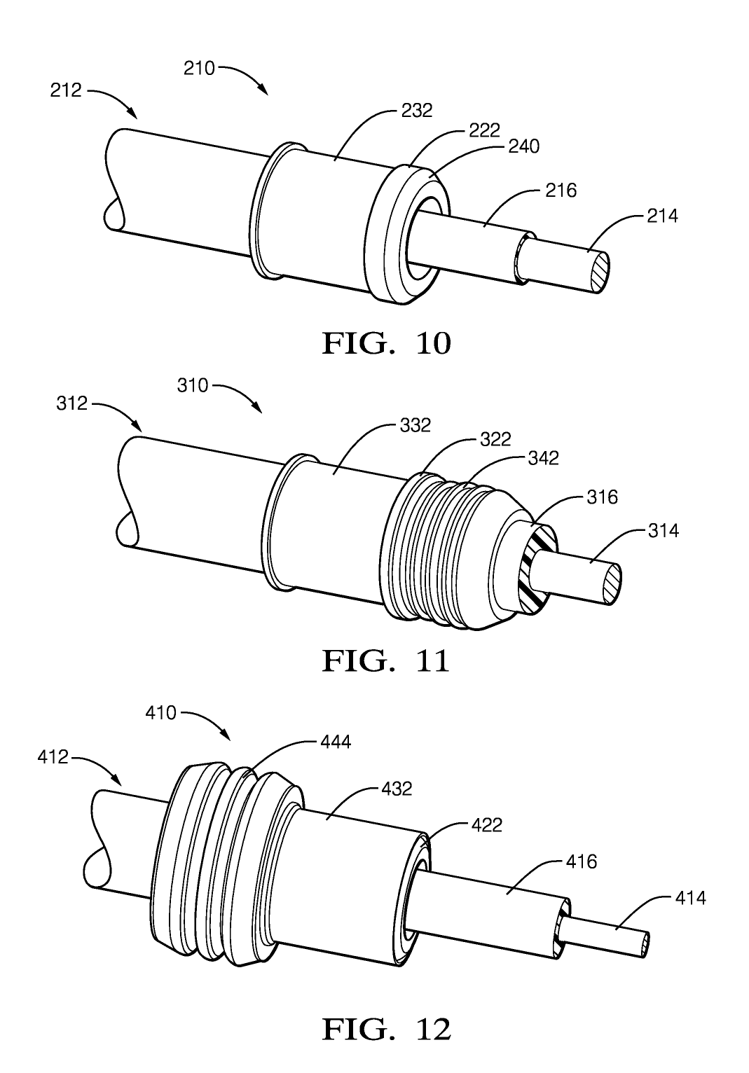

FIG. 10 illustrates an alternative embodiment of the terminal assembly 210 wherein the inner ferrule 222 includes an anti-creepage feature 240 in the form of an electrically insulative rib protruding beyond the outer ferrule 232 intermediate the outer ferrule 232 and a terminal (not shown) connected to the inner conductor 214. This feature may allow smaller connector package size for high voltage application where creepage between the inner connector and the outer ferrule 232 is a concern.

FIG. 11 illustrates another alternative embodiment of the terminal assembly 310 wherein the inner ferrule 322 includes an anti-vibration feature 342 in the form of a number of resilient ribs protruding beyond the outer ferrule 332 intermediate the outer ferrule 332 and a terminal (not shown) connected to the inner conductor 314 to dampen terminal vibration.

FIG. 12 illustrates yet another alternative embodiment of the terminal assembly 410 wherein the inner ferrule 422 includes sealing feature 444 in the form of a number of resilient ribs protruding beyond the outer ferrule 432 aft of the outer ferrule 432 that are configured to contact an inner surface of housing (not shown).

While the examples of the terminal assembly presented above illustrate a shielded cable having a braided outer conductor, other embodiments of the invention may be envision that are used with a shielded cable having foil or conductive film outer conductors.

Accordingly a terminal assembly 10 having an inner ferrule 22 formed of a resilient compressible dielectric material is provided. The terminal assembly 10 provides a cost advantage over prior art terminal assemblies 110 by replacing deep drawn or machined inner ferrules with a molded inner ferrule that can be produced inexpensively. One size inner ferrule may be molded to match required cable size which eliminates the need for multiple sizes of inner ferrules. The terminal assembly 10 may also allow some applications to use one outer ferrule size for multiple cable sizes. The inner ferrule 22 may be common to multiple applications. The inner ferrule 22 may be colored to provide visual differentiation between various sizes. The inner ferrule 22 provides increased insulation protection for the inner conductor and decrease the risk of piercing through the insulation of the core conductor. The inner ferrule 222 may incorporate features to reduce distance needed to avoid creepage in high voltage applications, allowing the outer ferrule to located closer to a terminal attached to the inner conductor. The inner ferrule 322 may incorporate features to provide additional terminal dampening for high vibration applications. The inner ferrule 422 may incorporate features to provide an integral cable seal. The terminal assembly 10 also provides more stands of outer conductor in contact with outer ferrule 32 and provides fewer voids between the inner ferrule and the outer ferrule 32. The terminal assembly 10 also meets or exceeds the pull off force compared to the prior art terminal assembly 110.

While this invention has been described in terms of the preferred embodiments thereof, it is not intended to be so limited, but rather only to the extent set forth in the claims that follow. Moreover, the use of the terms first, second, etc. does not denote any order of importance, but rather the terms first, second, etc. are used to distinguish one element from another. Furthermore, the use of the terms a, an, etc. do not denote a limitation of quantity, but rather denote the presence of at least one of the referenced items.

We claim:

1. A terminal assembly configured to terminate a shielded cable having an inner conductor, an inner insulator surrounding the inner conductor, an outer conductor surrounding the inner insulator, and an outer insulator surrounding the outer conductor, said terminal assembly comprising:
a generally cylindrical outer ferrule formed of a conductive material; and
a generally cylindrical inner ferrule formed of a resilient compressible dielectric material, wherein the at least a portion of the inner ferrule is disposed within the outer ferrule and a portion of the shielded cable is disposed within the inner ferrule and wherein a portion of the outer conductor is disposed intermediate the inner ferrule and the outer ferrule and is in intimate contact therewith.

2. The terminal assembly according to claim 1, wherein the resilient compressible dielectric material is a silicone-based material.

3. The terminal assembly according to claim 1, wherein the resilient compressible dielectric material has a Shore A durometer hardness between 30 and 80.

4. The terminal assembly according to claim 1, wherein the inner ferrule has a generally constant outside diameter.

5. The terminal assembly according to claim 1, wherein the outer ferrule is crimped to the inner ferrule and wherein the inner ferrule is elastically deformed by the outer ferrule.

6. The terminal assembly according to claim 5, wherein an inner surface of the outer ferrule defines a projection configured to contact and indent the outer conductor and the inner ferrule.

7. The terminal assembly according to claim 6, wherein the inner ferrule defines a circumferential rib protruding beyond the outer ferrule.

8. The terminal assembly according to claim 7, wherein the inner ferrule defines a plurality of circumferential ribs protruding beyond the outer ferrule and wherein an outer diameter of each circumferential rib is substantially uniform.

9. The terminal assembly according to claim 8, wherein the plurality of circumferential ribs are resilient.

10. A terminal assembly terminating a shielded cable wherein a metallic inner wire cable covered by an inner insulator is sheathed by braided metallic wires on an outer periphery of the inner insulator and further covered by an outer insulator surrounding the braided metallic wires and wherein the braided metallic wires are exposed at one end of the shielded cable, said terminal assembly comprising:
a generally cylindrical inner ferrule formed of a resilient compressible dielectric material inserted between the outer insulator and the exposed braided metallic wires bent back over the inner ferrule; and
a generally cylindrical outer ferrule formed of a conductive material crimped over the exposed braided metallic wires, wherein at least a portion of the inner ferrule is disposed within the outer ferrule and wherein a portion of the exposed braided metallic wires are disposed intermediate the inner ferrule and the outer ferrule and is in intimate contact therewith.

11. The terminal assembly according to claim 10, wherein the resilient compressible dielectric material is a silicone-based material.

12. The terminal assembly according to claim 10, wherein the resilient compressible dielectric material has a Shore A durometer hardness between 30 and 80.

13. The terminal assembly according to claim 10, wherein the inner ferrule has a generally constant outside diameter.

14. The terminal assembly according to claim 10, wherein an inner surface of the outer ferrule defines a projection configured to contact and indent the exposed braided metallic wires and the inner ferrule.

15. The terminal assembly according to claim 10, wherein the inner ferrule defines a circumferential rib protruding beyond the outer ferrule.

16. The terminal assembly according to claim 15, wherein the inner ferrule defines a plurality of circumferential ribs protruding beyond the outer ferrule and wherein an outer diameter of each circumferential rib is substantially uniform.

17. The terminal assembly according to claim 16, wherein the plurality of circumferential ribs are resilient.
